(19) United States
(12) Patent Application Publication
(10) Pub. No.: US 2010/0303259 A1
(43) Pub. Date: Dec. 2, 2010

(54) ELECTRONIC DEVICE AND METHOD FOR USING THE SAME

(75) Inventor: Li-Jin JIA, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/633,096

(22) Filed: Dec. 8, 2009

(30) Foreign Application Priority Data
Jun. 2, 2009 (CN) 200910302845.5

(51) Int. Cl. H03G 3/00; G06F 17/00; G08B 17/00

(52) U.S. Cl. 381/107; 700/94; 340/584

(57) ABSTRACT

An electronic device includes an audio module, a processor module connected to the audio module, and a sensor module connected to the processor module. The processor module directs the sensor module to detect temperatures at predetermined positions when the audio module plays back audio content, and the processor module regulates the playback volume or turns off the audio module according to the detected temperatures.

### BACKGROUND

1. Technical Field

The present disclosure relates to electronic devices, and particularly to an electronic device capable of playing music and a method for using the same.

2. Description of Related Art

Many persons like listening to music to be relaxed when they are sleepy. Nowadays, sleep function has long been provided in many electronic devices, such as radios, MP3 players, mobile phones, and personal digital assistants (PDA), and others.

During use of the sleep function, however, which often constitutes a simple timer, volume of the music often requires regulation. However, attention to regulation of the volume contradicts the purpose of the sleep function itself. Additionally, since the duration of the sleep timer is preset, the devices may continue to function long after needed, consuming excess electrical power.

Therefore, there is room for improvement within the art.

### BRIEF DESCRIPTION OF THE DRAWINGS

Many aspects of the present electronic device and method for using the same can be better understood with reference to the following drawings. The components in the various drawings are not necessarily drawn to scale, the emphasis instead being placed upon clearly illustrating the principles of the present electronic device and method for using the same. Moreover, in the drawings, like reference numerals designate corresponding parts throughout the figures.

FIG. 1 is a block diagram of an electronic device, according to an exemplary embodiment.

FIG. 2 is a flowchart of a method for using an electronic device, such as, for example, that shown in FIG. 1.

### DETAILED DESCRIPTION

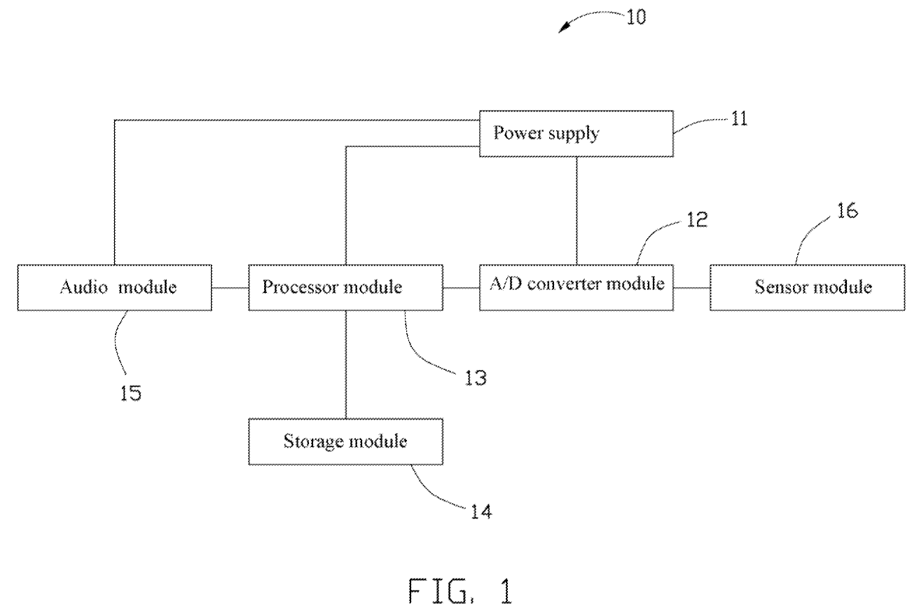

FIG. 1 schematically shows an electronic device 10 capable of playing music, according to an exemplary embodiment. The electronic device 10 can be a radio, an MP3 player, a mobile phone, a personal digital assistant (PDA), or other. The electronic device 10 includes a power supply 11, an analog/digital (A/D) converter module 12, a processor module 13, a storage module 14, an audio module 15, and at least one sensor module 16.

The sensor module 16, the A/D converter module 12, the processor module 13, and the audio module 15 are electronically connected in series. The sensor module 16 is a temperature sensor that detects ambient temperature and generate analog voltage signals corresponding thereto. The A/D converter module 12 receives the analog voltage signals generated by the sensor module 16, converts the analog signals into digital signals and transmit the digital signals to the processor module 13. The processor module 13 can be a central processing module (CPU) of the electronic device 10. The processor module 13 receives the digital signals from the A/D converter module 12 and calculates the ambient temperatures accordingly. The audio module 15 can be a conventional speaker or earphone through which audio files played back by the audio module 15 are outputted. The volume of the audio module 15 is regulated by the processor module 13, which can further turn the audio module 15 on/off.

The storage module 14, electrically connected to the processor module 13, stores ambient temperatures data calculated by the processor module 13 at predetermined times and based on relative functional parameters, such as detection time, storage time, detection duration and a change range. Additionally, the storage module 14 can also store audio files to be played back by the audio module 15.

The power supply 11 is electronically connected to the A/D converter module 12, the processor module 13 and the audio module 15. The power supply 11 supplies electric power to the A/D converter module 12, the processor module 13 and the audio module 15.

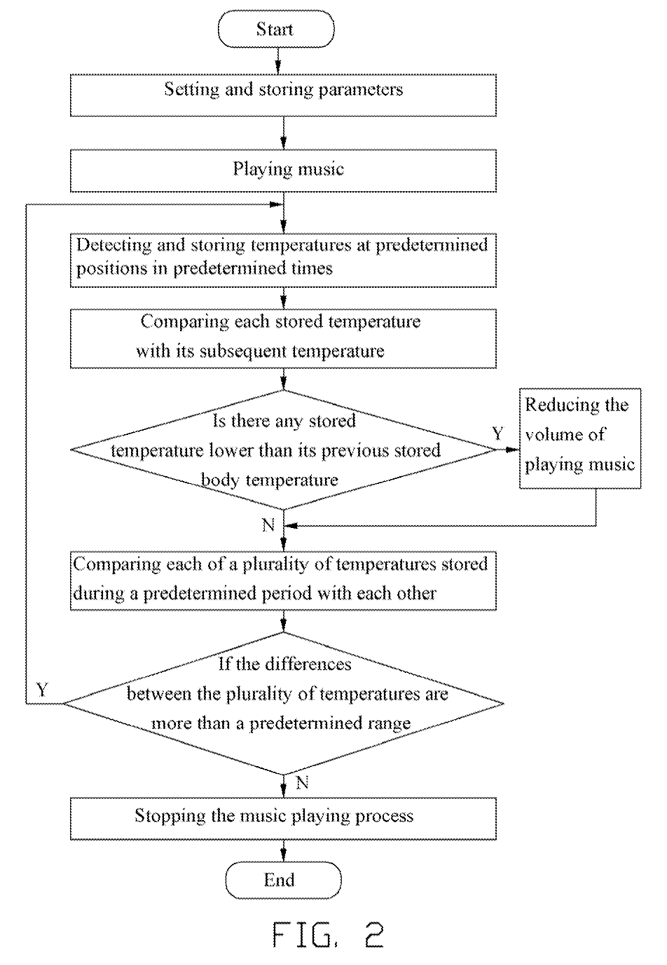

FIG. 2 shows a method for using an electronic device, which is provided as follows.

First, an electronic device 10 is provided. Relative parameters for using the electronic device 10 are set and stored in the storage module 14. The parameters can include temperature detection time, storage time, and a detection duration and a change range.

When a sleep function is to be enabled, the electronic device 10 operates to play back audio files stored in the storage module 14 by the audio module 15. The sensor module 16 is positioned to contact or to be adjacent to predetermined positions on the body of a user. The sensor module 16 continuously detects the body temperature of the user and outputs analog voltage signals corresponding to the detected temperature. The analog voltage signals are received by the A/D converter module 12 and are converted into digital voltage signals which are received by the processor module 13. For each predetermined temperature detection duration, the processor module 13 calculates the body temperature of the user according to the received digital voltage signals. The calculated body temperature is then stored in the storage module 14 in predetermined storage time.

When at least two detected temperature values are stored in the storage module 14, the processor module 13 compares each stored body temperature with the subsequent stored body temperature. Since body temperatures are generally higher when awake than when sleeping, the processor module 13 determines that sleep is imminent when a stored body temperature falls below the previous stored body temperature. Accordingly, the processor module 13 automatically reduces music volume. If the processor module 13 determines, based on a stored body temperature equaling or exceeding its previous stored body temperature, that the user is wakening, the processor module 13 maintains the original volume setting.

After the processor module 13 determines that sleep is imminent and a plurality of body temperatures has been stored during a predetermined detection duration, the processor module 13 compares the body temperatures stored during the detection duration with each other. Generally, body temperature changes relatively more while awake than asleep. Accordingly, if the differences between the plurality of body temperatures stored during the detection duration are more than the predetermined change range, the processor module 13 identifies that the user is asleep and automatically turns off the audio module 15. If the differences between the plurality of body temperatures stored during the detection duration are more than the predetermined change range, the processor module 13 identifies that the user is awake and continues playing music by the audio module 15 and detecting the body temperature of the user according to the aforementioned steps.

The processor module 13 can also directly determine if the user is asleep according to the currently determined body temperature. Generally, body temperatures are relatively higher (more than 37° C.) when a person is awake, rather than asleep. Therefore, a benchmark temperature for determining if the user is sleeping can be predetermined and stored in the storage module 14, such as, for example, 37° C. The benchmark temperature can also be regulated according to practical physiological data of individual users. In use, the processor module 13 determines that the user is sleeping when the currently calculated body temperature of the user falls below the benchmark temperature, and thus turns off the audio module. On the contrary, the processor module 13 determines that the user is awake when the measured body temperature of the user exceeds the benckmark temperature, and audio continues to be played back by the audio module 15.

According to the present method, the electronic device 10 can detect the body temperature of the user thereof and determine the condition of the user according to the detected body temperature thereof. When the electronic device 10 determines that sleep is imminent or occurring, it automatically regulates the volume or turns off the audio module 15, correspondingly.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. An electronic device, comprising:
an audio module;
a processor module connected to the audio module; and
at least one sensor module connected to the processor module; wherein the processor module directs the sensor module to detect temperatures in predetermined locations when the audio module plays back audio content, and the processor module regulates the playback volume or turns off the audio module according to the detected temperatures.

2. The electronic device as claimed in claim 1, further comprising an A/D converter module connected between the sensor module and the processor module.

3. The electronic device as claimed in claim 1, further comprising a storage module connected to the processor module, in which the detected temperatures are stored.

4. The electronic device as claimed in claim 3, wherein the processor module compares each stored temperature with the subsequent stored temperature, and regulates the playback volume accordingly.

5. The electronic device as claimed in claim 4, wherein the processor module reduces the playback volume when a stored temperature falls below the previous stored temperature.

6. The electronic device as claimed in claim 4, wherein the processor module maintains the original playback volume when a stored temperature equals or exceeds the previous stored temperature.

7. The electronic device as claimed in claim 3, wherein the processor module compares each of a plurality of temperatures stored during a predetermined period, and thus turns off the audio module when the differences between the plurality of body temperatures stored in the detecting method are not more than a predetermined range.

8. The electronic device as claimed in claim 3, wherein the processor module turns off the audio module when a currently detected temperature falls below a predetermined benchmark temperature.

9. A method for using an electronic device to play audio files, comprising:
the electronic device playing back audio content;
detecting temperatures in predetermined locations; and
automatically regulating the playback volume or stopping playback according to the detected temperatures.

10. The method as claimed in claim 9, further comprising setting and storing relative parameters for using the electronic device.

11. The method as claimed in claim 10, wherein the relative parameters include temperature detection time, storage time, a detection duration and a change range.

12. The method as claimed in claim 11, further comprising storing the detected temperatures in predetermined storage times.

13. The method as claimed in claim 12, further comprising comparing each stored temperature with the subsequent stored temperature, and regulating the playback volume according to the comparison results.

14. The method as claimed in claim 13, further comprising reducing the playback volume when a stored temperature falls below the previous stored temperature.

15. The method as claimed in claim 13, further comprising maintaining the original playback volume when a stored temperature equals or exceeds the previous stored temperature.

16. The method as claimed in claim 12, further comprising comparing each of a plurality of temperatures stored during a predetermined period and stopping playback when the differences between the plurality of temperatures stored in the detecting method are not more than a predetermined range.

17. The method as claimed in claim 12, wherein the relative parameters further include a predetermined benchmark temperature.

18. The method as claimed in claim 17, further comprising stopping audio content playback when a currently detected temperature falls below the benchmark temperature.
